(19) United States
(12) Patent Application Publication
(10) Pub. No.: US 2007/0281396 A1
(43) Pub. Date: Dec. 6, 2007

(54) Method of Dissipating heat, Packaging and Shaping for Light Emitting Diodes

(76) Inventors: Hung-Tsung Hsu, Lujhu Township (TW); Steven Lu, Lujhu Township (TW); Chieh Lu, Lujhu Township (TW); Su-Chi Chang, Lujhu Township (TW)

Correspondence Address: HDSL, 4331 STEVENS BATTLE LANE, FAIRFAX, VA, 22033, US

(21) Appl. No.: 11/421,570

(22) Filed: Jun. 1, 2006

(51) Int. Cl. H01L 21/00

(52) U.S. Cl. 438/122

(57) ABSTRACT

A method of dissipating heat, packaging and shaping for light emitting diodes enhances the heat dissipation performance of light emitting diodes, and its structure includes a substrate and a light emitting diode chip. An antioxidation is performed at a high temperature at a predetermined position for installing a chip on the surface of the substrate; a layer of intermetallic layer is coated; a solder material is placed on the intermetallic layer and at the predetermined position of the chip; an intermetallic layer is also coated onto the adhering surface of the chip; the adhering surface of the chip is coupled with the solder material; meanwhile the intermetallic layer and the solder material are heated by furnace to form a stable metal alloy structure, so that the chip can be fixed onto the substrate; and finally the light emitting diode structure is completed by a wirebond process.

### BACKGROUND OF THE INVENTION

1. Field of the Invention

The present invention relates to a light emitting diode, and more particularly to a light emitting diode structure having a heat conducting structure.

2. Description of Prior Art

As the technology of manufacturing light emitting diodes advances constantly and the development of new materials for producing light emitting diodes undergoes a change more rapidly than ever, high power light emitting diodes with high capacity and efficiency are introduced, and thus the current passing through unit area becomes increasingly larger, and the heat produced by the LED chip becomes increasingly higher. However, the material for packaging the light emitting diodes usually adopts a resin compound having a thermal insulation effect, and the thermal conduction effect is poor. If such material wraps around the whole chip and electrode circuits, the operating heat cannot be dissipated successfully, so that an environment having a heat reservation and sealing effect will be formed. As a result, the operating heat will attenuate the light emitting diode and become one of the major factors that affects the light emitting efficiency.

The aforementioned light emitting diode package structure for installing a surface mount technology (SMT) chip or a leadframe becomes the best heat dissipating path. Further, it is necessary to install a layer of solder material between the chip and the substrate to fix the position of the substrate onto the light emitting diode chip. Since the heat dissipating path and efficiency must be taken in consideration for the package structure of the light emitting diode, therefore the solder material must be selected deliberately. In prior arts, a silver paste (Ag paste) is usually used, because the silver paste can effectively fix the chip and the substrate (or leadframe) in their respective positions and also quickly dissipating the operating heat of the chip to the outside through the heat conduction of the silver paste while the light emitting diode chip is operating, so as to avoid an influence of the operating heat on the light emitting diode chip and prevent an optical attenuation of the light emitting diode.

However, the operating heat of the high power light emitting diode is increased significantly, so that if the current of the light emitting diode is larger than a specific value, then the thermal conductivity and the coefficient of thermal expansion of the prior art silver paste cannot bear the operating heat. As a result, a light attenuation of the light emitting diode chip will give rise to an insufficient light or even will disable the light emitting diode. Therefore, the prior art needs to take the popular application of the high power light emitting diode and the brightness into consideration. Further, the operating heat is increased considerably, and thus the material of the substrate (or leadframe) with a high conductivity and a high coefficient of thermal expansion close to those of the light emitting diode chip is used, and an alloy material such as lead-tin alloy (PbSn), tin-silver alloy (AgSn) or indium (In) is used as a solder material to enhance the efficiency of the thermal conduction of the light emitting diode.

Since most substrates are made of a highly thermal conductive material such as copper, or tin for the process of connecting the chip with the substrate, it is necessary to melt the alloy of the solder material at a high temperature into a liquid and then mount the chip onto the substrate. However, an oxidation occurs at the surface of the substrate primarily made of copper or tin due to the high temperature, and thus the adhesiveness of the alloy of the solder material with the substrate will be affected aversely and become insufficient. Furthermore, the chip and the alloy material of the solder material cannot form an intermetallic structure, and the drawback of an insufficient adhesiveness also exists. As a result, the light emitting diode structure may fall come off easily and the efficiency of conducting and dissipating the operating heat will be affected when the light emitting diode is operating. Therefore, the aforementioned problems demands immediate attentions and feasible solutions.

### SUMMARY OF THE INVENTION

In view of the foregoing shortcomings of the prior art, the inventor of the present invention based on years of experience in the related industry to conduct experiments and modifications, and finally designed a feasible solution to overcome the shortcomings of the prior art.

Therefore, the present invention is to overcome the shortcomings of the prior art by providing a method of dissipating heat, packaging and shaping for light emitting diodes, wherein an antioxidation is conducted at a predetermined surface of the substrate of the light emitting diode chip, and a layer of intermetallic layer is plated onto the surface for connecting the substrate and the chip, and a solder material is provided and coupled to the intermetallic layer to form a stable metal alloy. Such arrangement not only enhances the adhesiveness of the solder material for fixing the relative positions of the chip and the substrate, but also serves as a thermal conducting path for dissipating heat.

The invention provides a method of dissipating heat, packaging and shaping light emitting diodes, and its structure includes a substrate and a light emitting diode chip, wherein an antioxidation is conducted at a high temperature at a predetermined position for installing a chip on the surface of the substrate; a layer of intermetallic layer is coated; a solder material is placed on the intermetallic layer and at the predetermined position of the chip; an intermetallic layer is coated onto the adhering surface of the chip; the adhering surface of the chip is coupled with the solder material; meanwhile the intermetallic layer and the solder material are heated by furnace to form a stable metal alloy structure, so that the chip can be fixed onto the substrate; and finally the light emitting diode structure is completed by a wirebond process.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIGS. 1A and 1B are cross-sectional views of a manufacturing flow of the invention;

FIG. 2 is a cross-sectional view of another manufacturing flow of the invention;

FIG. 3 is a cross-sectional view of a further manufacturing flow of the invention;

FIG. 4 is a cross-sectional view of another further manufacturing flow of the invention;

FIG. 5 is a flow chart of a manufacturing flow of the invention; and

FIG. 6 is a cross-sectional view of a wirebond process according to another preferred embodiment of the invention.

### DETAILED DESCRIPTION OF THE INVENTION

The technical characteristics, features and advantages of the present invention will become apparent in the following detailed description of the preferred embodiments with reference to the accompanying drawings. However, the drawings are provided for reference and illustration only and are not intended for limiting the scope of the invention.

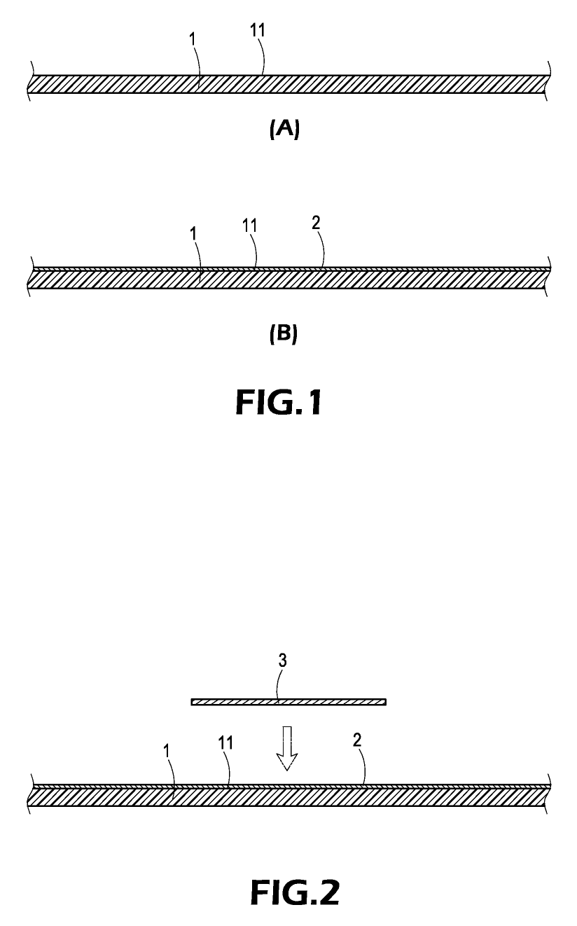

Referring to FIGS. 1 to 4 for the cross-sectional views of manufacturing flows of the present invention, a surface mount technology (SMT) light emitting diode is adopted in these embodiments, and the light emitting diode structure comprises a substrate 1 used as an intermetallic material of an intermetallic layer 2, a solder material 3 and a light emitting diode chip 4. In FIGS. 1A and 1B, a substrate 1 is provided, and the substrate 1 is made of a highly thermal conductive material such as copper or aluminum, and also could be a printed circuit board (PCB) having a heat dissipating effect. After the substrate 1 is heated at a temperature of 300° C. or above by a furnace, a liquid nitrogen (N₂) is sprinkled onto a predetermined mounting surface 11 of the substrate 1 for a surface treatment to prevent an oxidation occurred at the mounting surface 11 of the substrate 1 at a high temperature, and thus the chip cannot be mounted. A layer of intermetallic layer 2 is plated onto a predetermined mounting surface 11 of the substrate 1 by a manufacturing technology, and the intermetallic layer 2 is made of gold, tin-gold or silver, and the substrate 1 having the intermetallic layer 2 is placed onto a manufacturing tool.

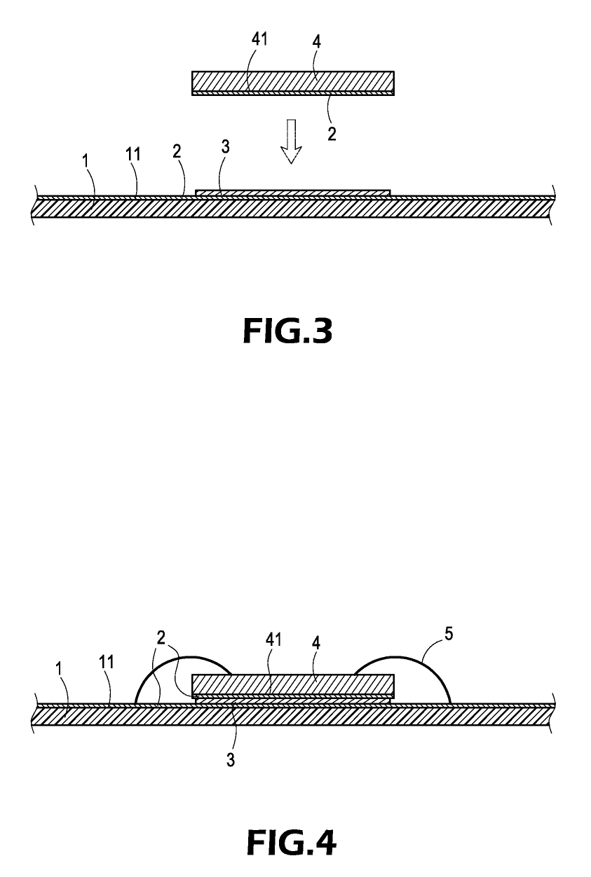

In FIG. 2, an appropriate amount of a sheet solder material 3 is placed at a predetermined position of the intermetallic layer 2 of the chip 4, and the solder material 3 is an alloy material such as a tin-gold (AuSn) alloy or a tin-silver (AgSn) alloy that can be coupled with the intermetallic layer 2 easily. In FIG. 3, a layer of intermetallic layer 2 is plated onto a adhering surface 41 of light emitting diode chip 4 that is intended to be connected with the substrate 1, and then the chip 4 is placed on the top of the solder material 3, so that the adhering surface 41 of the chip 4 can be combined with the solder material 3. In the meantime, the foregoing structure is heated at a high temperature, so that the solder material 3 is melted, and the chip 4 is moved sideway at the connecting position in order to coat the solder material 3 evenly onto the substrate 1 and the intermetallic layer 2 of the chip 4. In FIG. 4, a metal alloy structure is securely coupled to the substrate 1 and the intermetallic layer 2 of the chip 4 after the solder material 3 is cooled down, so that the chip 4 can be mounted completely onto the substrate 1. Finally, a leading wire 5 is connected by using a wirebond technology to form an anode and a cathode and complete the structure of the light emitting diode.

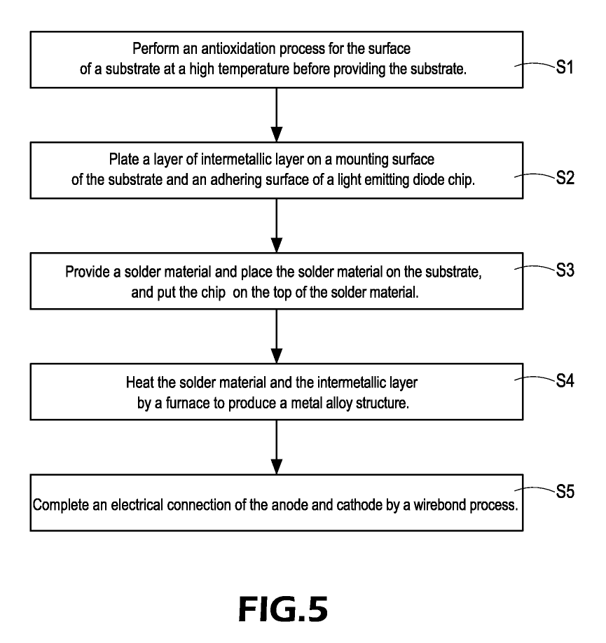

Referring to In FIG. 5 for the flow chart of a manufacturing flow of the invention, a substrate 1 is provided, and an antioxidation process is performed on the mounting surface 41 of the substrate 1 at a high temperature by using a liquid nitrogen (Step S1); a layer of the intermetallic layer 2 is plated onto a mounting surface 41 of the substrate 1 and an adhering surface 41 of the light emitting diode chip 4 (Step S2); a solder material 3 is placed onto a predetermined position of the intermetallic layer 2 of the chip material of the substrate 1, and then the chip 4 is placed on the solder material 3 (Step S3); a thermal treatment is performed by a furnace, so that the solder material 3 can be coated evenly on the mounting surface 11 of the substrate 1 and the adhering surface 41 of the chip 4 to form a stable metal alloy structure (Step S4); and finally an anode and a cathode are connected by a wirebond process (Step 5) to complete the light emitting diode structure.

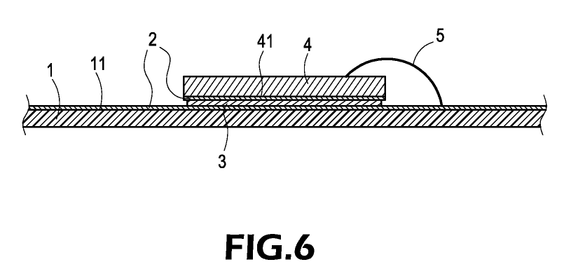

Further, the aforementioned manufacturing method is applicable for surface mount technology (SMT) light emitting diodes or frame type light emitting diodes and used for connecting the heat dissipating frame and the chip. In FIG. 6, the anode and cathode of the light emitting diode structure are installed on the same surface of the chip 4 by using the wirebond technology or an alloy structure on the adhering surface 41 of the chip 4 is connected electrically, and a leading wire 5 is connected to the front side of the chip 4 such that the leading wire 5 becomes the anode and the adhering surface 41 of the chip 4 becomes a cathode, or vice versa.

In summation of the above description, the invention herein enhances the performance than the conventional structure and further complies with the patent application requirements.

The present invention are illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method of dissipating heat, packaging and shaping for light emitting diodes, comprising the steps of:
providing a substrate and a light emitting diode chip, and performing an antioxidation process on a surface of the substrate at a high temperature;
plating a layer of intermetallic layer on a surface for jointing the substrate and the chip;
providing a solder material and placing the solder material on the substrate, and put the chip on top of the solder material; and
heating the solder material and the intermetallic layer by a furnace to produce a metal alloy structure for securing a connecting position of the chip and the substrate.

2. The method of claim 1, wherein the substrate is made of a highly thermal conductive material.

3. The method of claim 1, wherein the substrate is made of a material containing copper metal.

4. The method of claim 1, wherein the substrate is made of a material containing aluminum metal.

5. The method of claim 1, wherein the substrate is a printed circuit board.

6. The method of claim 1, wherein the high temperature is 300° C. or above.

7. The method of claim 1, wherein the antioxidation process further includes a step of sprinkling a liquid nitrogen (N₂) on the surface of the substrate.

8. The method of claim 1, wherein the intermetallic layer is made of gold.

9. The method of claim 1, wherein the intermetallic layer is made of tin.

10. The method of claim 1, wherein the intermetallic layer is made of silver.

11. The method of claim 1, wherein the solder material is made of an alloy.

12. The method of claim 1, wherein the solder material is made of a tin-gold (AuSn) alloy.

13. The method of claim 1, wherein the solder material is made of a tin-silver (AgSn) alloy.

14. The method of claim 1, further comprising the step of:
completing an electrical connection of the anode and cathode through the leading wire by a wirebond process.

15. The method of claim 14, wherein the anode and cathode of a leading wire are disposed on the same surface of the chip.

16. The method of claim 15, wherein the single electrode is installed onto a surface of the chip through a leading wire.
